(19) United States
(12) Patent Application Publication
(10) Pub. No.: US 2012/0204793 A1
(43) Pub. Date: Aug. 16, 2012

(54) LED PACKAGE MANUFACTURING SYSTEM

(75) Inventor: Masaru Nonomura, Osaka (JP)

(73) Assignee: PANASONIC CORPORATION, Osaka (JP)

(21) Appl. No.: 13/503,695

(22) PCT Filed: May 9, 2011
(86) PCT No.: PCT/JP2011/002577

§ 371 Date: Apr. 24, 2012

(30) Foreign Application Priority Data
Sep. 9, 2010 (JP) 2010-201653

(51) Int. Cl. H01L 21/00

(52) U.S. Cl. 118/696; 118/712

(57) ABSTRACT

There are preliminarily prepared element characteristic information 12 that is obtained by individually, previously measuring emission characteristics of a plurality of LED elements and resin coating information 14 that makes a coating quantity of resin appropriate for obtaining an LED package exhibiting a specified emission characteristic correlated with the element characteristic information. A map preparation processing section 74 prepares, for each substrate, map data 18 that correlate populating position information 71 a showing a position of an LED element populated on the substrate by a component populating machine Ml with the element characteristic information 12. According to the map data 18 and the resin coating information 14, a resin coating machine M4 coats the respective LED elements populated on the substrate with an appropriate coating quantity of resin.

### TECHNICAL FIELD

The present invention relates to an LED package manufacturing system that manufactures an LED package formed by covering an LED element populated on a substrate with a phosphor-containing resin.

### BACKGROUND ART

LEDs (light-emitting diode) exhibiting superior characteristics; namely, less power consumption and a longer life, have come into extensive use as light sources for various illuminating devices. The fundamental light emitted from an LED element is currently limited to the three primary lights; red light, green light, and blue light. For this reason, in order to generate white light suitable for general illumination purposes, there has been employed a technique of generating white light by mixing the three fundamental lights through additive color mixture or a technique of generating pseudo white light by combination of a blue LED with a phosphor that emits yellow fluorescent light which is complementary to a blue color. In recent years, the latter technique has come into wide use. An illuminating device using an LED package that is a combination of a blue LED and YAG phosphor has widely been used for a backlight of a liquid-crystal panel (see; for instance, Patent Document 1).

In this example Patent Document, an LED element is populated on a bottom of a recessed populating section having sidewalls over which a reflection surface is formed. Subsequently, a silicone resin, an epoxy resin, or the like, that includes dispersed YAG-based phosphor particles is poured into the populating section, thereby forming a resin package section. An LED package is thus configured. There are also descriptions about example formation of a surplus resin storage section that is intended for providing a uniform height to the resin package section formed in the populating section after pouring of a resin and preserving a surplus resin which has been poured in excess of a specified quantity and hence drained out of the resin populating section. Even when variations exist in discharge rate of a dispenser during pouring of a resin, a resin package section having a given quantity of resin and a defined height is formed on an LED element.

### RELATED ART DOCUMENT

### Patent Document

Patent Document 1: JP-A-2007-66969

### SUMMARY OF THE INVENTION

### Problem that the Invention is to Solve

However, a problem confronted by the related art example is that a change in emission characteristic of an LED package which is to become a product is caused by a variation in emission wavelength of an individual LED element change. Specifically, LED elements have passed through a manufacturing process in which a plurality of elements are collectively fabricated on a wafer. For reasons of various error factors in the manufacturing process; for instance, uneven composition occurred when a film is formed over a wafer, LED elements separated as pieces from the wafer are inevitably subject to variations in emission wavelength. In the foregoing example, the height of the resin package covering the LED element is uniformly set. Hence, variations in emission wavelength of respective individual LED elements are reflected as variations in emission characteristic of LED packages that are products. As a consequence, an increase inevitably arises in the number of defective products that are out of an acceptable quality range. As mentioned above, the related-art LED package manufacturing technique has hitherto encountered the following problem; specifically, because of variations in emission wavelength of respective LED elements, variations arise in emission characteristic of LED packages that are products, which in turn causes deterioration of product yield.

Accordingly, the present invention aims at providing an LED package manufacturing system that, even when variations occur in emission wavelength of respective LED elements, can make emission characteristics of LED packages uniform, to thus enhance product yield.

### Means for Solving the Problem

An LED package manufacturing system of the present invention corresponds to an LED package manufacturing system that manufactures an LED package which is formed by covering an LED element populated on a substrate with a phosphor-containing resin, the system comprising:

a component populating machine that populates the plurality of LED elements on the substrate;

an element characteristic information providing unit that provides, as element characteristic information, information obtained by preliminarily, individually measuring emission characteristics including emission wavelengths of the plurality of LED elements;

a resin information providing unit that provides, as resin coating information, information which makes a coating quantity of resin appropriate for obtaining an LED package having a specified emission characteristic correlated with the element characteristic information;

a map data preparation unit that prepares, for each substrate, map data which correlate populating position information showing positions of then LED elements populated on the substrate by the component populating machine with the element characteristic information about the LED element; and

a resin coating machine that coats, according to the map data and the resin coating information, the respective LED elements populated on the substrate with the coating quantity of resin appropriate for exhibiting the specified emission characteristic.

### Advantage of the Invention

Even when variations occur in emission wavelength of respective LED elements, the present invention can make emission characteristics of LED packages uniform, to thus enhance product yield.

### BRIEF DESCRIPTION OF THE DRAWINGS

FIG. 1 is a block diagram showing a configuration of an LED package manufacturing system of an embodiment of the present invention.

FIG. 2(a) and (b) are descriptive views of a configuration of an LED package manufactured by the LED package manufacturing system of the embodiment of the present invention.

FIGS. 3(a), (b), (c), and (d) are descriptive views of a supply form of and element characteristic information about an LED element used in the LED package manufacturing system of the present embodiment of the present invention.

FIG. 4 is a descriptive view of resin coating information used in the LED package manufacturing system of the embodiment of the present invention.

FIGS. 5(a), (b), and (c) are descriptive views of a configuration and function of a component populating machine in the LED package manufacturing system of the embodiment of the present invention.

FIG. 6 is a descriptive view of map data used in the LED package manufacturing system of the embodiment of the present invention.

FIG. 7(a) and (b) are descriptive views of a configuration and function of a resin coating machine in the LED package manufacturing system of the embodiment of the present invention.

FIG. 8 is a descriptive view of a configuration of an emission characteristic inspection machine in the LED package manufacturing system of the embodiment of the present invention.

FIG. 9 is a block diagram showing a configuration of a control system of the LED package manufacturing system of the embodiment of the present invention.

FIG. 10 is a flowchart pertaining to manufacture of an LED package implemented by the LED package manufacturing system of the embodiment of the present invention.

FIGS. 11(a), (b), (c), and (d) are descriptive process charts showing processes for manufacturing an LED package in the LED package manufacturing system of the embodiment of the present invention.

FIGS. 12(a), (b), (c), and (d) are descriptive process charts showing processes for manufacturing an LED package in the LED package manufacturing system of the embodiment of the present invention.

### EMBODIMENT FOR IMPLEMENTING THE INVENTION

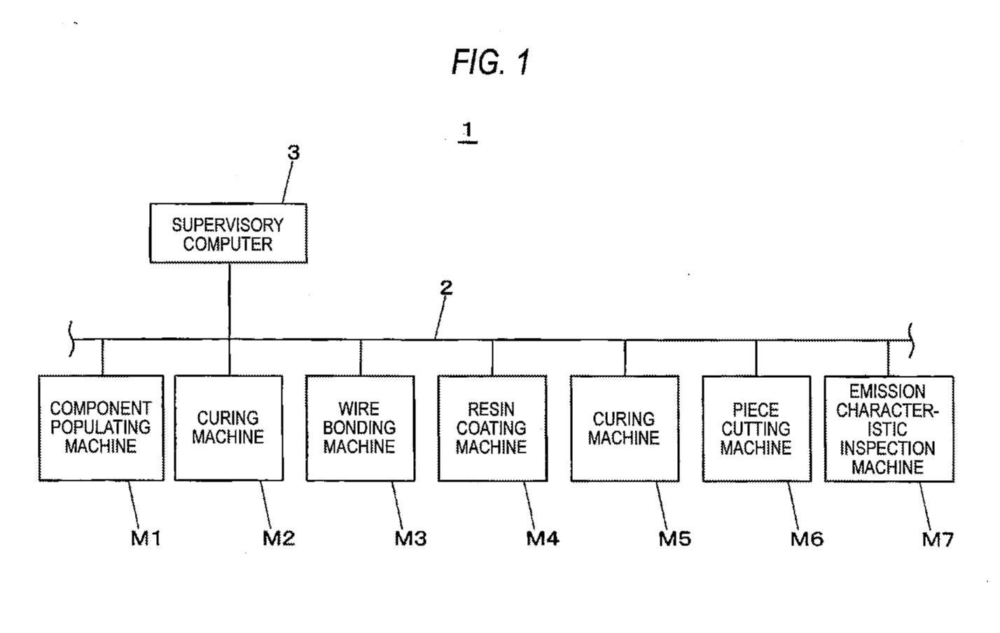

By reference to the drawings, an embodiment of the present invention will now be described. First, a configuration of an LED package manufacturing system 1 is described by reference to FIG. 1. The LED package manufacturing system 1 has a function of manufacturing an LED package in which an LED element populated on a substrate is covered with a phosphor-containing resin. As shown in FIG. 1, in the present embodiment, the LED package manufacturing system is configured in such a way that a component populating machine M1, a curing machine M2, a wire bonding machine M3, a resin coating machine M4, a curing machine M5, a piece cutting machine M6, and an emission characteristic inspection machine M7 are connected together by a LAN system 2, and the machines are collectively controlled by a supervisory computer 3.

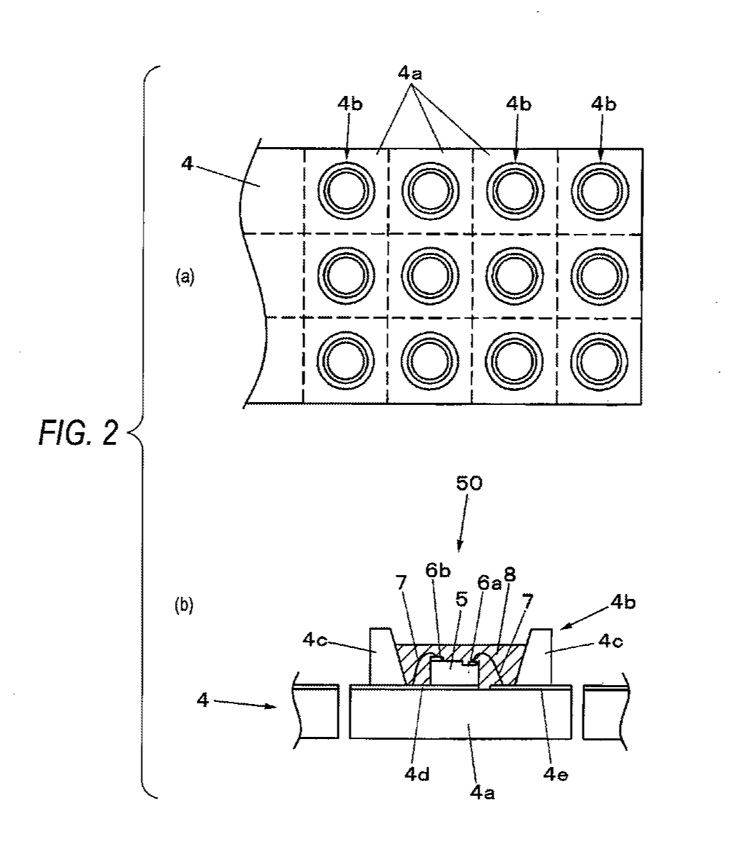

The component populating machine M1 bonds and populates LED elements 5 on a substrate 4 (see FIG. 2), which is to serve as a base of an LED package, with a resin adhesive. The curing machine M2 heats the substrate 4 populated with the LED elements 5, thereby curing the resin adhesive used for bonding during populating operation. The wire bonding machine M3 connects electrodes of the substrate 4 to electrodes of the LED elements 5 by wire bonding. The resin coating machine M4 coats the wire-bonded substrate 4 with a phosphor-containing resin for each of the LED elements 5. The curing machine M5 heats the substrate 4 coated with the resin, thereby curing the applied resin so as to cover the LED elements 5. The piece cutting machine M6 cuts the substrate 4 whose resin has been cured into respective pieces of the LED elements 5, whereby the LED elements are separated into individual LED packages. The emission characteristic inspection machine M7 subjects completed LED packages divided into pieces to inspection in connection with an emission characteristic, such as a color hue, and performs processing for feeding back an inspection result, as required.

FIG. 1 illustrates an example configuration of a production line where the machines, or the component populating machine M1 to the emission characteristic inspection machine M7, are arranged in line. However, it is not necessary to adopt such a line configuration for the LED package manufacturing system 1. So long as information, which will be mentioned in the following descriptions, is appropriately transferred, there may also be adopted a configuration in which the respective machines installed at dispersed positions sequentially perform work pertaining to respective steps. Moreover, a plasma processing machine that performs plasma processing intended for cleaning electrodes before performance of wire-bonding may also be disposed before or after the wire bonding machine M3. Further, a plasma processing machine that performs plasma processing intended for surface modification in order to enhance adhesion of a resin prior to performance of resin coating may also be disposed after wire-bonding operation.

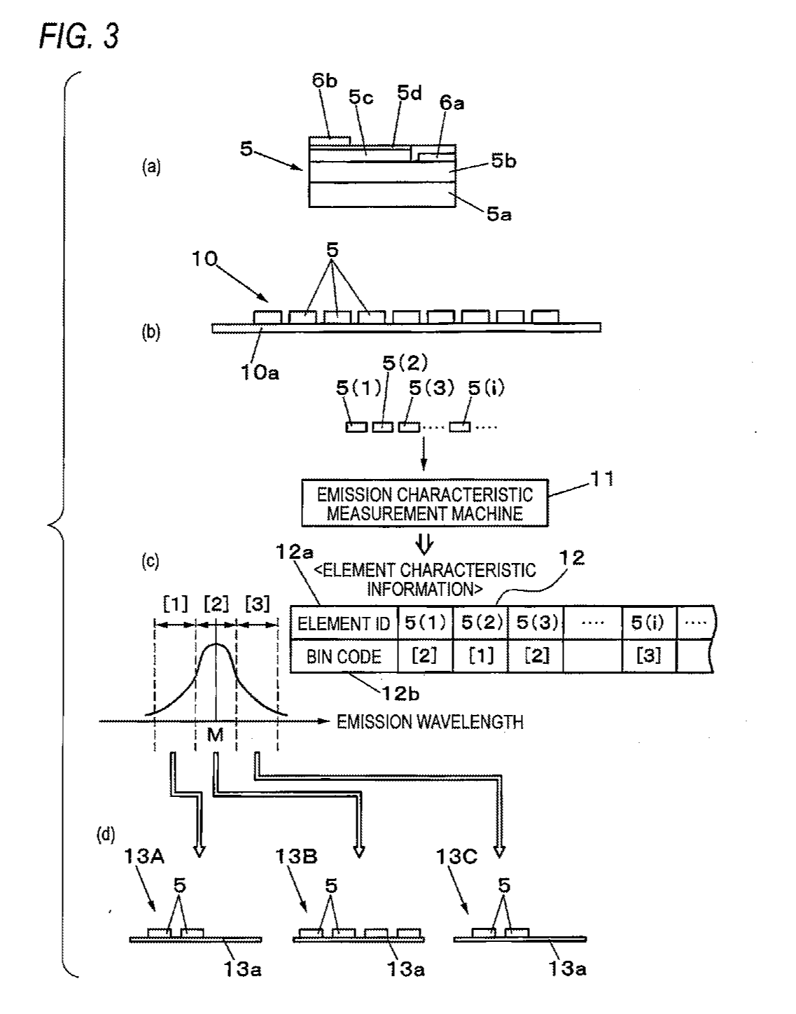

By reference to FIGS. 2 and 3, an explanation is given to the substrate 4 and the LED element 5 that are work objects in the LED package manufacturing system 1 and an LED package 50 that is a completed product. As shown in FIG. 2(a), the substrate 4 is a multi-board. The multi-board includes a plurality of substrate pieces 4a that are to become bases for respective completed LED packages 50. An LED populating section 4b on which the LED element 5 is to be populated is formed in each of the substrate pieces 4a. The LED element 5 is populated in the LED populating section 4b on each of the substrate pieces 4a. Subsequently, a resin 8 is applied to an interior of the LED populating section 4b, thereby covering the LED element 5. Further, the substrate 4 having finished undergoing processing pertaining to the step is cut into the substrate pieces 4a after curing of the resin 8, whereby the LED packages 50 shown in FIG. 2(b) are completed.

Each of the LED packages 50 has a function of emitting white light used as light sources of various illuminating devices. The LED element 5 that is a blue LED is combined with the resin 8 that includes a phosphor which emits yellowish fluorescent light that is a complementary color of blue, whereby pseudo white light is produced. As shown in FIG. 2(b), a cavity-shaped reflection section 4c with; for instance, a circular or oval annular dike, that forms the LED populating section 4b is provided on each substrate piece 4a. An N-type electrode 6a of the LED element 5 populated in the reflection section 4c is connected to a wiring layer 4e formed on an upper surface of the corresponding substrate piece 4a by a bonding wire 7. A P-type electrode 6b of the LED element 5 is connected to a wiring layer 4d formed on the upper surface of the substrate piece 4a by the bonding wire 7. The resin 8 is applied to the interior of the reflection section 4c to a predetermined thickness, thereby covering the LED element 5 in this state. During the course of blue light emitted from the LED element 5 passing through and exiting from the resin 8, the blue light is mingled with yellow light emitted from the phosphor included in the resin 8, whereupon white light is emitted.

As shown in FIG. 3(a), the LED element 5 is fabricated by layering an N-type semiconductor 5b and a P-type semiconductor 5c, in this sequence, on a sapphire substrate 5a; and covering a surface of the P-type semiconductor 5c with a transparent electrode 5d. Thus, the N-type electrode 6a for external connection use is fabricated on the N-type semiconductor 5b, and the P-type electrode 6b for external connection use is fabricated on the P-type semiconductor 5c. As shown in FIG. 3(b), after the plurality of LED elements 5 have been collectively fabricated, the LED elements 5 are taken, while being separated into pieces, out of an LED wafer 10 adhesively held by a holding sheet 10a. In relation to the LED elements 5, variations unavoidably occur in light emitting characteristics, such as emission wavelengths, of the respective LED elements 5 that have been separated into pieces from the wafer, for reasons of various error factors in manufacturing processes; for instance, composition unevenness occurring during formation of a film like a wafer. If the respective LED elements 5 are populated, as they are, on the respective substrates 4, variations will arise in emission characteristics of the respective LED packages 50 that are products.

In order to prevent occurrence of a quality defect attributable to variations in emission characteristics, emission characteristics of the plurality of LED elements 5 manufactured through the same manufacturing processes are preliminarily measured in the embodiment. Element characteristic information that correlates the respective LED elements 5 with data representing emission characteristics of the respective LED elements 5 is preliminarily prepared. During application of the resin 8, each of the LED elements 5 is coated with an appropriate quantity of resin 8 commensurate with the emission characteristic of the LED element 5. Since an appropriate quantity of resin 8 is applied, resin coating information to be described later is previously prepared.

First, element characteristic information is described. As shown in FIG. 3(c), each of the LED elements 5 taken out of the LED wafer 10 is imparted with an element ID for identifying an individual LED element [an individual LED element 5 is identified by a serial number (i) allocated to the LED wafer 10 in the embodiment], and the LED elements 5 are sequentially loaded into an emission characteristic measurement machine 11. Any information can be used as the element ID, so long as the information enables individual identification of the LED element 5. An element ID of another data format; for instance, matrix coordinates showing an array of the LED elements 5 on the LED wafer 10, can also be used as it is. Use of such an element ID enables the component populating machine M1, which will be described later, to feed the LED elements 5 in the form of the LED wafer 10.

In the emission characteristic measurement machine 11, electric power is fed to the respective LED elements 5 by a probe, thereby letting the LED elements actually emit light. The thus-emitted light is subjected to spectroscopic analysis and measured in connection with predetermined items; like, an emission wavelength and emission intensity. The LED element 5 that is an object of measurement has preliminarily been provided with, as reference data, a standard distribution of an emission wavelength. Further, a wavelength range corresponding to a standard range in the distribution is divided into a plurality of wavelength regions. The plurality of LED elements 5 that are objects of measurement are thereby classified according to an emission wavelength. Respective ranks, which are set as a result of a wavelength range being classified into three regions, are given, in sequence from a lower wavelength, Bin codes [1], [2], and [3]. There is prepared element characteristic information 12 including a data configuration in which element ID 12a is allocated to Bin code 12b.

Specifically, the element characteristic information 12 is information obtained by preliminarily, individually measuring emission characteristics including respective emission wavelengths of the plurality of LED elements 5. An LED element manufacturer preliminarily prepares the information, and the information is transmitted to the LED package manufacturing system 1. In relation to a form of transmission of the element characteristic information 12, the information may also be transmitted while solely recorded in a storage medium or to the supervisory computer 3 by the LAN system 2. In any event, the thus-transmitted element characteristic information 12 is stored in the supervisory computer 3 and provided to the component populating machine M1, as required.

The plurality of LED elements 5 having finished undergoing emission characteristic measurement are sorted into three types of characteristic ranks as shown in FIG. 3(d). The thus-sorted LED elements 5 are respectively affixed to three adhesive sheets 13a. Thus, there are made three types of LED sheets 13A, 13B, and 13C that adhesively hold the LED elements 5 corresponding to the respective Bin codes [1], [2], and [3] by the adhesive sheets 13a. When the LED elements 5 are populated on the substrate pieces 4a of the substrate 4, the LED elements 5 are fed to the component populating machine M1 in the form of the LED sheets 13A, 13B, and 13C that have already been ranked. The supervisory computer 3 at this time provides the element characteristic information 12 to each of the LED sheets 13A, 13B, and 13C so as to represent correspondence between the LED elements 5 on the respective sheets 13A, 13B, and 13C and the Bin codes [1], [2], and [3].

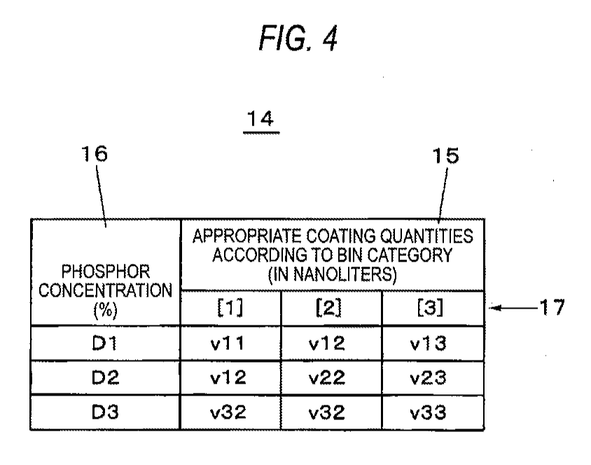

Resin coating information preliminarily prepared in correspondence with the element characteristic information 12 is now described by reference to FIG. 4. In an LED package 50 configured so as to generate white light by combination of the blue LED with a YAG-based phosphor, the blue light emitted by the LED element 5 is mingled with yellow light emitted as a light of the phosphor being excited by the blue light through additive color mixture. Therefore, a quantity of phosphor particles in the recessed LED populating section 4b where the LED element 5 is to be populated becomes important in assuring an emission characteristic specified by the produced LED package 50.

As mentioned above, variations classified by the Bin codes [1], [2], and [3] concurrently exist in emission wavelengths of the plurality of LED elements 5 that are objects of work. For this reason, an appropriate quantity of phosphor particles in the resin 8 applied so as to cover the LED element 5 varies according to the Bin codes [1], [2], and [3]. As shown in FIG. 4, in relation to the resin 8 containing YAG-based phosphor particles in a silicon resin, an epoxy resin, or the like, resin coating information 14 provided in the present embodiment preliminarily specifies appropriate coating quantities of the resin 8, which are arranged according to a Bin category, in nanoliters according to a Bin code category 17.

As provided in a phosphor concentration field 16, a phosphor concentration showing the concentration of phosphor particles in the resin 8 is set in numbers (three concentrations D1, D2, and D3 in the embodiment). A different numeral is also used for an appropriate coating quantity of resin 8 according to a concentration of phosphor in the resin 8 used. The reason why different appropriate application quantities are set according to the phosphor concentration is because applying the resin 8 having an optimum phosphor concentration according to a degree of variation in emission wavelength is more desirable from the viewpoint of securing quality. For instance, when the LED element 5 given Bin code [2] in connection with the Bin code category 17 is taken as a target, it is desirable to set an appropriate discharge rate in such a way that the resin 8 having a phosphor concentration D2 is squirted by only a quantity of v22nl. As a matter of course, when the resin 8 having a single phosphor concentration is used for reasons, an appropriate discharge rate commensurate with the Bin code category 17 is selected according to the phosphor concentration.

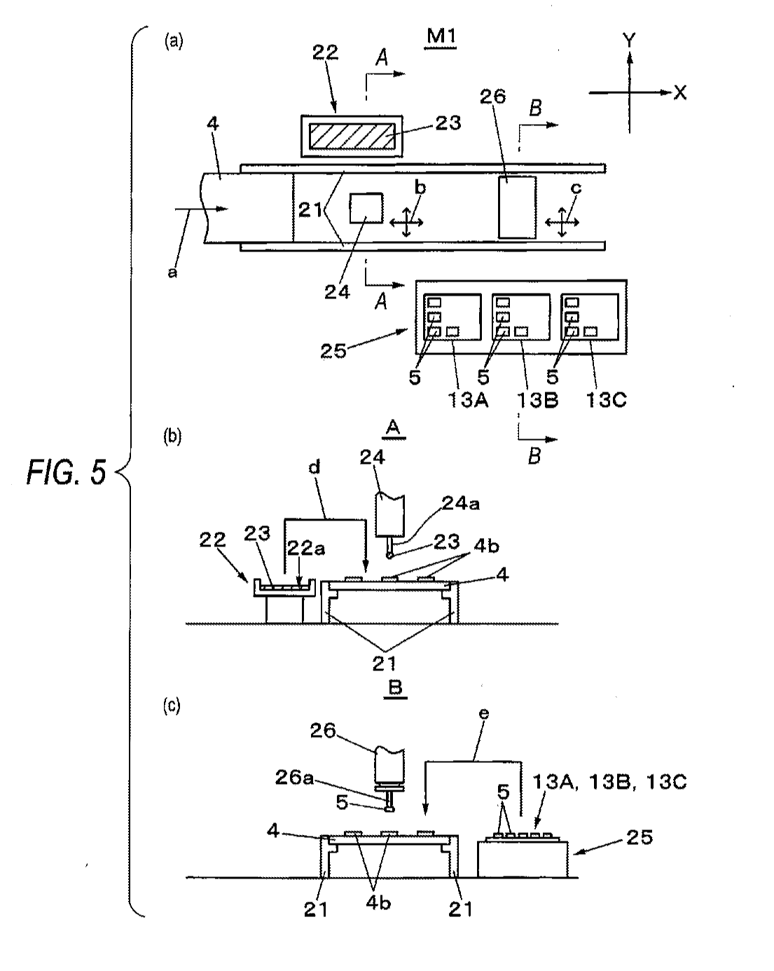

By reference to FIG. 5, a configuration and function of the component populating machine M1 are now described. As shown in a plan view of FIG. 5(a), the component populating machine M1 has a substrate transport mechanism 21 that transports the substrate 4, which is fed from an upstream position and which is an object of work, in a substrate transport direction (an arrow “a”). An adhesive coating section A illustrated in cross section A-A shown in FIG. 5(b) and a component populating section B illustrated in cross section B-B shown in FIG. 5(c) are provided, in this sequence from an upstream side, in the substrate transport mechanism 21. The adhesive coating section A has an adhesive feed section 22 that is disposed at the side of the substrate transport mechanism 21 and that feeds a resin adhesive 23 in the form of a coating film having a predetermined thickness and an adhesive transfer mechanism 24 that is movable in a horizontal direction (an arrow “b”) above the substrate transport mechanism 21 and the adhesive feed section 22. The component populating section B has the substrate transport mechanism 21 and a component feed mechanism 25 that is disposed at the side of the substrate transport mechanism 21 and that holds the LED sheets 13A, 13B, and 13C shown in FIG. 3(d); and a component populating mechanism 26 that is movable in a horizontal direction (an arrow “c”) above the substrate transport mechanism 21 and the component feed mechanism 25.

As shown in FIG. 5(b), the substrate 4 carried into the substrate transport mechanism 21 is positioned by the adhesive coating section A, and the resin adhesive 23 is applied to the respective LED populating sections 4b formed in the respective substrate pieces 4a. Specifically, the adhesive transfer mechanism 24 is moved to a position above the adhesive feed section 22, where a transfer pin 24a is brought into contact with a coating film of the resin adhesive 23 formed on a transfer surface 22a, whereupon the resin adhesive 23 is bonded. Next, the adhesive transfer mechanism 24 is moved to a position above the substrate 4, and the transfer pin 24a is lowered to the LED populating sections 4b (arrow “d”), whereby the resin adhesive 23 adhering to the transfer pin 24a is fed to an element populating position in the LED populating sections 4b by transfer operation.

The substrate 4 coated with the adhesive is transported downstream and positioned by the component populating section B as shown in FIG. 5(c), and the LED element 5 is populated to each of the LED populating sections 4b having been fed with an adhesive. First, the component populating mechanism 26 is moved to a position above the component feed mechanism 25, and a population nozzle 26a is lowered to any one of the LED sheets 13A, 13B, and 13C held by the component feed mechanism 25. The population nozzle 26a picks up to hold the LED element 5. Next, the component populating mechanism 26 is moved to a position above the LED populating section 4b of the substrate 4, whereupon the population nozzle 26a is lowered (arrow “e”). The LED element 5 held by the population nozzle 26a is thereby populated on the element populating position that is located within the LED populating section 4b and that is coated with an adhesive.

During operation for populating the LED element 5 onto the substrate 4 performed by the component populating machine M1, component populating operation is carried out according to a preliminarily-prepared element population program. The element population program preliminarily sets a sequence in which the component populating mechanism 26 picks up the LED elements 5 from which one of the LED sheets 13A, 13B, and 13C during individual populating operation and populates the thus-picked-up LED elements 5 respectively on the plurality of substrate pieces 4a of the substrate 4.

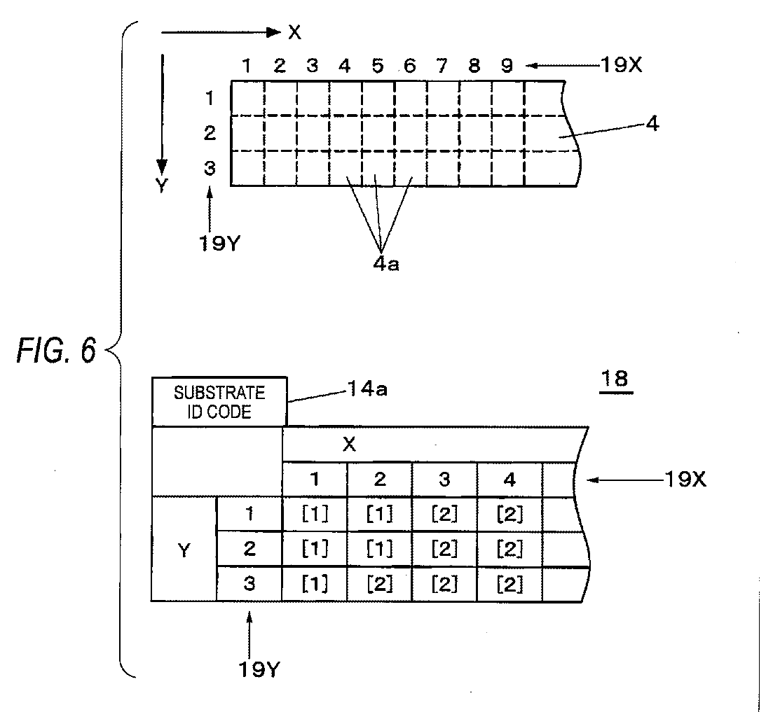

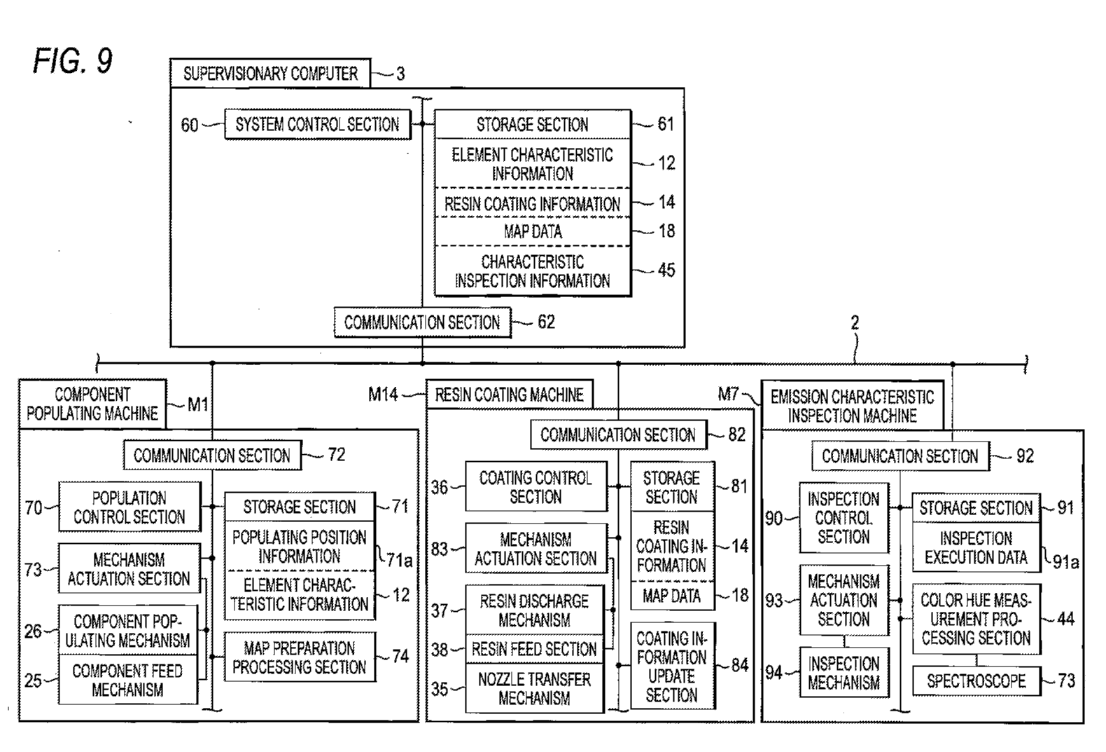

When component populating operation is performed, populating position information 71a (see FIG. 9) showing that one each LED element 5 is populated on which one of the plurality of substrate pieces 4a of the substrate 4 from work performance history, and the thus-extracted populating position information is recorded. A map preparation processing section 74 (see FIG. 9) prepares, as map data 18 shown in FIG. 6, data that correlate the populating position information 71a with the element characteristic information 12 showing that the individual LED element 5 populated on the substrate piece 4a corresponds to which one of characteristic ranks (Bin codes [1], [2], and [3]).

In FIG. 6, the position of each of the plurality of substrate pieces 4a of the substrate 4 is specified by a combination of matrix coordinates 19X and 19Y respectively showing a position in the X direction and a position in the Y direction. An individual cell of matrices defined by the matrix coordinates 19X and 19Y is caused to correspond to the Bin code to which the LED element 5 populated on the position belongs. There are thereby generated the map data 18 that correlate the populating position information 71a showing the position of the LED element 5 populated by the component populating machine M1 on the substrate 4 with the element characteristic information 12 about the LED element 5.

Specifically, the component populating machine M1 is equipped with the map preparation processing section 74 that serves as map data preparation unit for preparing for each substrate 4 the map data 18 which correlate the populating position information showing the position of the LED element 5 populated on the substrate 4 by the component populating machine with the element characteristic information 12 about the LED element 5. The thus-prepared map data 18 are transmitted as feedforward data to the resin coating machine M4 to be described later, by the LAN system 2.

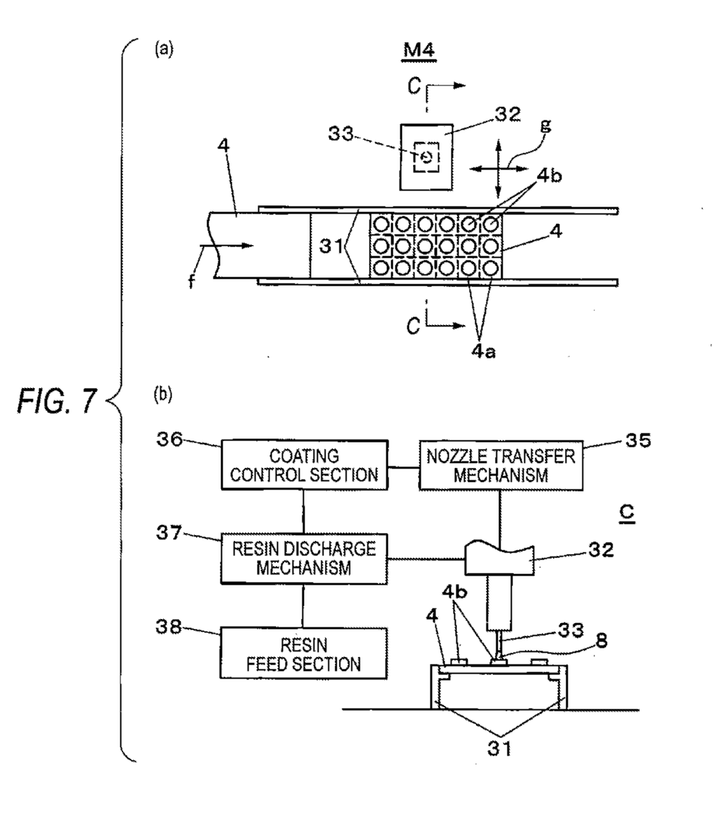

By reference to FIG. 7, the configuration and function of the resin coating machine M4 are now described. The resin coating machine M4 has a function of coating, with the resin 8, the plurality of LED elements 5 populated on the substrate 4 by the component populating machine M1. As represented by a plan view of FIG. 7(a), the resin coating machine M4 is configured in such a way that a substrate transport mechanism 31 for transporting in a substrate transport direction (arrow “f”) the substrate 4 which has been fed from an upstream position and which is a target of work is provided with a resin coating section C represented by a cross section C-C shown in FIG. 7(b). The resin coating section C is equipped with a resin discharge head 32 that has at its lower end a discharge nozzle 33 for discharging the resin 8.

As shown in FIG. 7(b), the resin discharge head 32 is actuated by a nozzle transfer mechanism 35, thereby performing a horizontal movement [arrow “g” shown in FIG. 7(a)] and ascending or descending operation with respect to the substrate 4 transported by the substrate transport mechanism 31. Therefore, the nozzle transfer mechanism 35 has made up a relative movement mechanism which relatively moves the discharge nozzle 33 with respect to the substrate 4. The resin coating machine M4 is equipped with a resin feed section 38 that feeds the resin 8 and a resin discharge mechanism 37 that discharges the resin 8 fed by the resin feed section 38 from the discharge nozzle 33. The resin feed section 38 may also be configured so as to store a plurality of types of resin 8 that are preliminarily given different phosphor contents, according to a plurality of types of phosphor concentrations specified by the resin coating information 14. The resin feed section 38 may also have a mixing mechanism capable of automatically adjusting a phosphor concentration and a function of automatically adjusting the resin 8 whose phosphor concentration indicated by the resin coating information 14.

The nozzle transfer mechanism 35 and the resin feed section 38 are controlled by a coating control section 36 and can thereby discharge the resin 8 by the discharge nozzle 33 to arbitrary LED populating sections 4b formed respectively on the plurality of substrate pieces 4a of the substrate 4. During resin discharge operation, the coating control section 36 controls the resin discharge mechanism 37, thereby controls the quantity of the resin 8 discharged from the discharge nozzle 33 to a desired quantity of resin according to an emission characteristic of the LED element 5 populated on each of the LED populating sections 4b.

Specifically, according to the preliminarily stored resin coating information 14 and the map data 18 transmitted from the component populating machine M1, the coating control section 36 controls the resin discharge mechanism 37 and the nozzle transfer mechanism 35 that is a relative transferring mechanism. This control makes it possible to cause the discharge nozzle 33 to discharge the quantity of resin 8 appropriate for exhibiting a specified emission characteristic, thereby coating the respective LED elements 5. As will be described later, a coating information update section 84 (see FIG. 9) always updates the resin coating information 14 on the basis of an inspection result of emission characteristic fed back from the emission characteristic inspection machine M7 disposed in a subsequent process. The coating control section 36 controls the resin discharge mechanism 37 and the nozzle transfer mechanism 35 according to the map data 18 and the resin coating information 14, to thus perform coating operation. History data pertaining to the coating operations are recorded in a storage section 81 (FIG. 9) as history data representing a history of manufacture of the LED packages 50. The supervisory computer 3 reads the history data as required.

Specifically, the resin coating machine M4 has a function of coating the respective LED elements 5 populated on the substrate 4 with the quantity of resin 8 appropriate for exhibiting a specified emission characteristic, according to the map data 18 and the resin coating information 14. Further, the resin coating machine M4 is additionally provided with the coating information update section 84 as coating information update unit for updating the resin coating information 14. Although FIG. 7 illustrates an example of the resin discharge head 32 having the single discharge nozzle 33, the resin discharge head 32 can also have a plurality of discharge nozzles 33 so that it can simultaneously coat the plurality of LED populating sections 4b with the resin 8. In this case, the resin discharge mechanism 37 individually controls the coating quantity for each of the discharge nozzles 33.

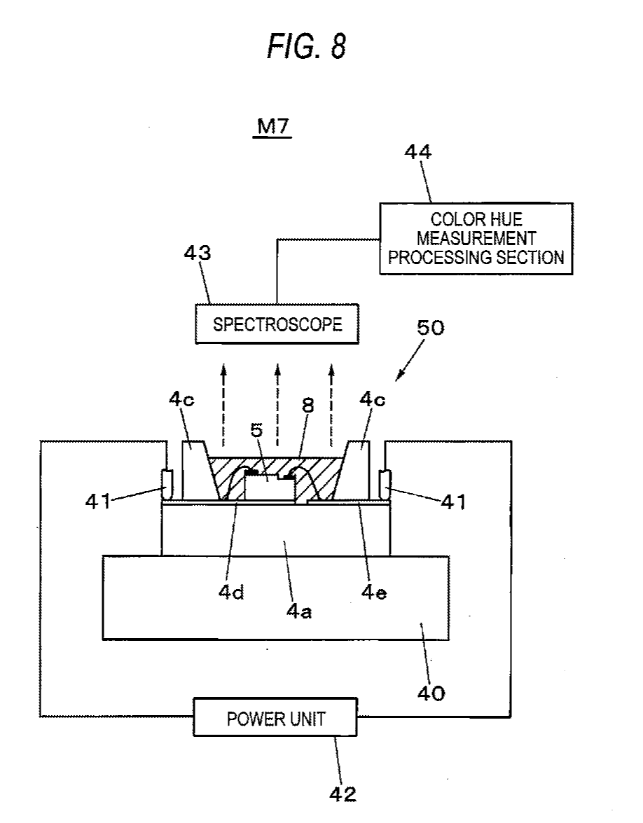

By reference to FIG. 8, the configuration of the emission characteristic inspection machine M6 is now described the emission characteristic inspection machine M6 has a function of inspecting whether or not the LED package 50 completed as a result of the substrate pieces 4a of the substrate 4 being separated after the resin 8 has been cured has a specified emission characteristic on a per-piece basis. As shown in FIG. 8, the LED packages 50 to be inspected is put on a holding table 40 placed in a dark room (omitted from the drawings) of the emission characteristic inspection machine M7. An inspection probe 41 remains in contact with the wiring layers 4e and 4d connected to the LED element 5 in each of the LED packages 50. The probe 41 is connected to a power unit 42. Electric power for emission purpose is supplied to the LED element 5 as a result of activation of the power unit 42, whereupon the LED element 5 emits blue light. In the course of the blue light passing through the resin 8, the phosphor in the resin 8 is excited, whereupon white light that is a result of additive color mixture of yellow light caused by excitation of the phosphor in the resin 8 with the blue light is emitted up from the LED package 50.

A spectroscope 43 is situated above the holding table 40 and receives the white light emitted from the LED package 50. A color hue measurement processing section 44 analyzes the thus-received white light. Emission characteristics of the white light, such as a color hue rank and a luminous flux, are inspected here, and deviation from specified emission characteristics is detected as inspection results. The thus-detected inspection results are fed back to the resin coating machine M4. When the deviation has exceeded a preset acceptable range, the resin coating machine M4 received the feedback performs processing for updating the resin coating information 14 according to the inspection result. Subsequently, coating the substrate 4 with a resin is thereafter performed according to the newly-updated resin coating information 14.

By reference to FIG. 9, a configuration of the control system of the LED package manufacturing system 1 is now described. There are illustrated, among constituent elements of the machines making up the LED package manufacturing system 1, constituent elements of the supervisory computer 3, the component populating machine M1, the resin coating machine M4, and the emission characteristic inspection machine M7 that correlate to transmission, receipt, and updating of the element characteristic information 12, the resin coating information 14, and the map data 18.

In FIG. 9, the supervisory computer 3 has a system control section 60, a storage section 61, and a communication section 62. The system control section 60 performs centralized control of LED package manufacturing operation performed by the LED package manufacturing system 1. In addition to storing programs and data required for control processing of the system control section 60, the storage section 61 stores the element characteristic information 12, the resin coating information 14. In addition, as required, the map data 18 and characteristic inspection information 45 to be described later are also stored in the storage section 61. The communication section 62 is connected to other units by the LAN system 2 and thereby exchanges a control signal and data. The element characteristic information 12 and the resin coating information 14 are transmitted from the outside and stored in the storage section 61 by the LAN system 2 and the communication section 62 or by a single storage medium, like CD-ROM.

The component populating machine M1 has a population control section 70, a storage section 71, a communication section 72, a mechanism actuation section 73, and the map preparation processing section 74. In order to implement component populating operation performed by the component populating machine M1, the population control section 70 controls individual sections, which will be described below, according to various programs and data stored in the storage section 71. In addition to storing programs and data required for control processing of the population control section 70, the storage section 71 stores the populating position information 71a and the element characteristic information 12. The populating position information 71a is prepared from data pertaining to a history of populating operation control performed by the population control section 70. The element characteristic information 12 is transmitted from the supervisory computer 3 by the LAN system 2. The communication section 72 is connected to other units by the LAN system 2 and thereby exchanges control signals and data.

Under control of the population control section 70, the mechanism actuation section 73 actuates the component feed mechanism 25 and the component populating mechanism 26. The LED elements 5 are thereby populated on the respective substrate pieces 4a of the substrate 4. The map preparation processing section 74 (map data preparation unit) performs processing for generating, for each substrate 4, the map data 18 that correlate the populating position information 71a, which is stored in the storage section 71 and which shows the position of the LED element 5 populated on the substrate 4 by the component populating machine M1, with the element characteristic information 12 about the LED element 5. Specifically, the map data preparation unit is provided on the component populating machine M1, and the map data 18 are transmitted from the component populating machine M1 to the resin coating machine M4. Alternatively, the map data 18 may also be transmitted from the component populating machine M1 to the resin coating machine M4 by the supervisory computer 3. In this case, the map data 18 are stored in the storage section 61 of the supervisory computer 3, as well, as shown in FIG. 9.

The resin coating machine M4 has the coating control section 36, the storage section 81, a communication section 82, a mechanism actuation section 83, and the coating information update section 84. In order to implement resin coating operation performed by the resin coating machine M4, the coating control section 36 controls individual sections to be described below, according to the various programs and data stored in the storage section 81. In addition to storing the programs and data required for control processing of the coating control section 36, the storage section 81 stores the resin coating information 14 and the map data 18. The resin coating information 14 is transmitted from the supervisory computer 3 by the LAN system 2. Likewise, the map data 18 are transmitted from the component populating machine M1 by the LAN system 2. The communication section 82 is connected to other units by the LAN system 2 and exchanges a control signal and data.

Under control of the coating control section 36, the mechanism actuation section 83 actuates the resin discharge mechanism 37, the resin feed section 38, and the nozzle transfer mechanism 35. The LED elements 5 populated on the respective substrate pieces 4a of the substrate 4 are thereby coated with the resin 8. In accordance with an inspection result fed back from the emission characteristic inspection machine M7, the coating information update section 84 performs processing for updating the resin coating information 14 stored in the storage section 81.

The emission characteristic inspection machine M7 has an inspection control section 90, a storage section 91, a communication section 92, a mechanism actuation section 93, and an inspection mechanism 94. In order to implement inspection operation performed by the emission characteristic inspection machine M7, the inspection control section 90 controls individual sections to be described below in accordance with inspection execution data 91a stored in the storage section 91. The communication section 92 is connected to other units by the LAN system 2 and exchanges a control signal and data. The mechanism actuation section 93 actuates an inspection mechanism 94 having a work transfer-hold function for handling the LED package 50 to inspect.

Under control of the inspection control section 90, the color hue measurement processing section 44 performs emission characteristic inspection for measuring a color hue of the white light originating from the LED package 50 received by the spectroscope 43. An inspection result is fed back to the resin coating machine M4 by the LAN system 2. Specifically, the emission characteristic inspection machine M7 has a function of inspecting an emission characteristic of the LED package 50 fabricated by coating the LED element 5 with the resin 8, thereby detecting a deviation from the specified emission characteristic, and feeding back the inspection result to the resin coating machine M4.

In the configuration shown in FIG. 9, processing functions other than functions for implementing work operations unique to the respective machines; for instance, the function of the map preparation processing section 74 provided in the component populating machine M1 and the function of the coating information update section 84 provided in the resin coating machine M4, do not necessarily come with the respective machines. For instance, the function of the map preparation processing section 74 and the function of the coating information update section 84 may also be covered by arithmetic processing function belonging to the system control section 60 of the supervisory computer 3, and necessary signals may also be exchanged by the LAN system 2.

In the configuration of the LED package manufacturing system 1, all of the component populating machine M1, the resin coating machine M4, and the emission characteristic inspection machine M7 are connected to the LAN system 2. The supervisory computer 3 having the element characteristic information 12 stored in the storage section 61 and the LAN system 2 serve as element characteristic information providing unit that provides information acquired by preliminary, individual measurement of emission characteristics including emission wavelengths of the plurality of LED elements 5, as the element characteristic information 12, to the component populating machine M1 Likewise, the supervisory computer 3 including the resin coating information 14 stored in the storage section 61 and the LAN system 2 serve as resin information providing unit that provides the resin coating machine M4 with, as resin coating information, information that correlates the coating quantity of resin 8 appropriate for producing the LED package 50 having a specified emission characteristic with the element characteristic information.

Specifically, the element characteristic information providing unit for providing the element characteristic information 12 to the component populating machine M1 and the resin information providing unit for providing the resin coating information 14 to the resin contacting machine M4 are configured so as to transmit to the component populating machine M1 and the resin coating machine M4 the element characteristic information and the resin coating information read from the storage section 61 of the supervisory computer 63 that is external storage unit, by the LAN system 2. Further, the emission characteristic inspection machine M7 is configured so as to transmit the inspection result, as the characteristic inspection information 45 (see FIG. 9), to the resin coating machine M4 by the LAN system 2. The characteristic inspection information 45 may also be transmitted to the resin coating machine M4 by the supervisory computer 3. In this case, as shown in FIG. 9, the characteristic inspection information 45 is stored in the storage section 61 of the supervisory computer 3, as well.

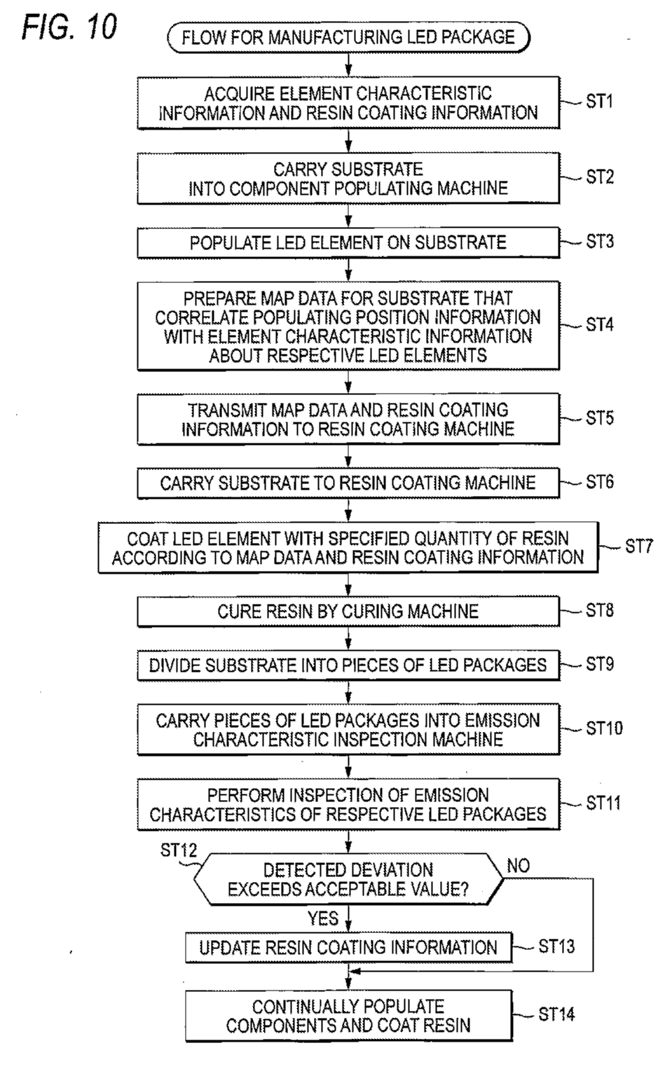

Processing pertaining to LED package manufacturing processes performed by the LED package manufacturing system 1 is now described along a flowchart of FIG. 10 and by reference to the drawings. First, the LED package manufacturing system 1 acquires the element characteristic information 12 and the resin coating information 14 (ST1). Specifically, the element characteristic information 12 obtained by preliminary, individual measurement of emission characteristics of the plurality of LED elements 5 including emission wavelengths and the resin coating information 14 that correlates the element characteristic information 12 with a coating quantity of resin 8 appropriate for producing the LED package 50 having the specified emission characteristic are acquired from an external device by the LAN system 2 or a storage medium.

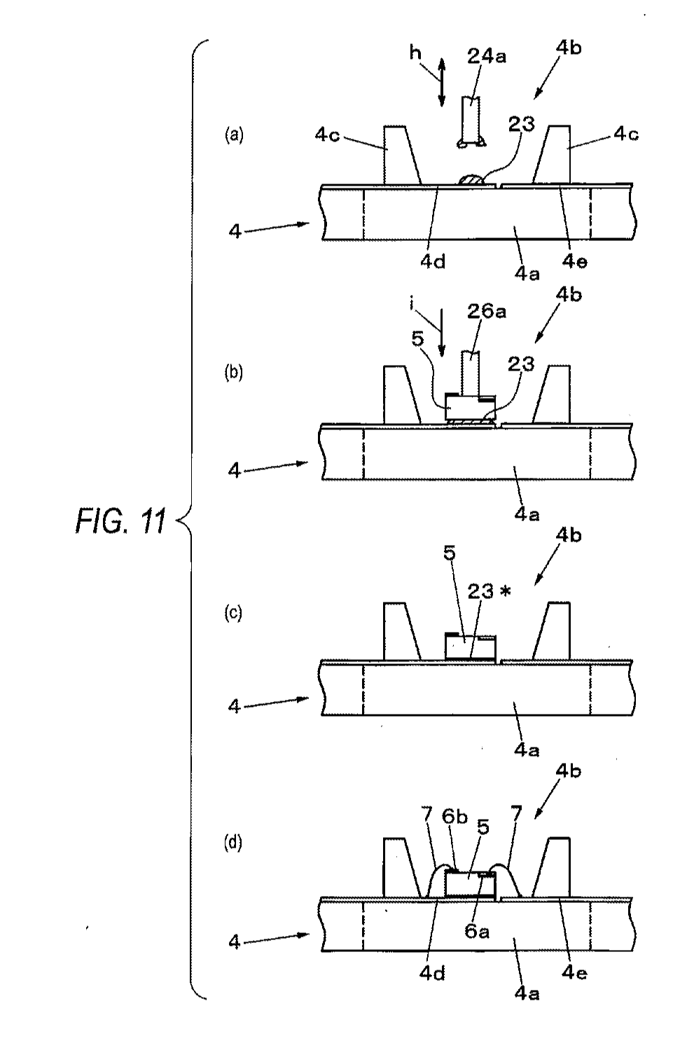

Subsequently, the substrate 4 that is an object of populating operation is carried into the component populating machine M1 (ST2). As shown in FIG. 11(a), in the component populating machine M1, the resin adhesive 23 has been supplied to the element populating position within the LED populating section 4b by the transfer pin 24a of the adhesive transfer mechanism 24. Subsequently, as shown in FIG. 11(b), the LED element 5 held by the population nozzle 26a of the component populating mechanism 26 is populated on the LED populating section 4b of the substrate 4 by the resin adhesive 23 (ST3). From data pertaining to performance of component populating operation, the map preparation processing section 74 prepares, with regard to this substrate 4, the map data 18 that correlates the populating position information 71a to the element characteristic information 12 about each of the LED elements 5 (ST4). Next, the map data 18 are transmitted from the component populating machine M1 to the resin coating machine M4, and the resin coating information 14 is transmitted from the supervisory computer 3 to the resin coating machine M4 (ST5). The resin coating machine M4 thereby comes into a state of being able to perform resin coating operation.

The substrate 4 having finished being populated with components is then sent to the curing machine M2, where the substrate 4 is heated. As shown in FIG. 11(c), the resin adhesive 23 becomes thermally cured, to thus turn into a resin adhesive 23*. The LED element 5 is then fixed to a corresponding substrate piece 4a. Subsequently, the substrate 4 whose resin has been cured is sent to the wire bonding machine M3. As shown in FIG. 11(d), the wiring layer 4e of the substrate piece 4a is connected to the N-type electrode 6a of the LED element 5 by the bonding wire 7, and the wiring layer 4d of the substrate piece 4a is connected to the P-type electrode 6b of the LED element 5 by the bonding wire 7.

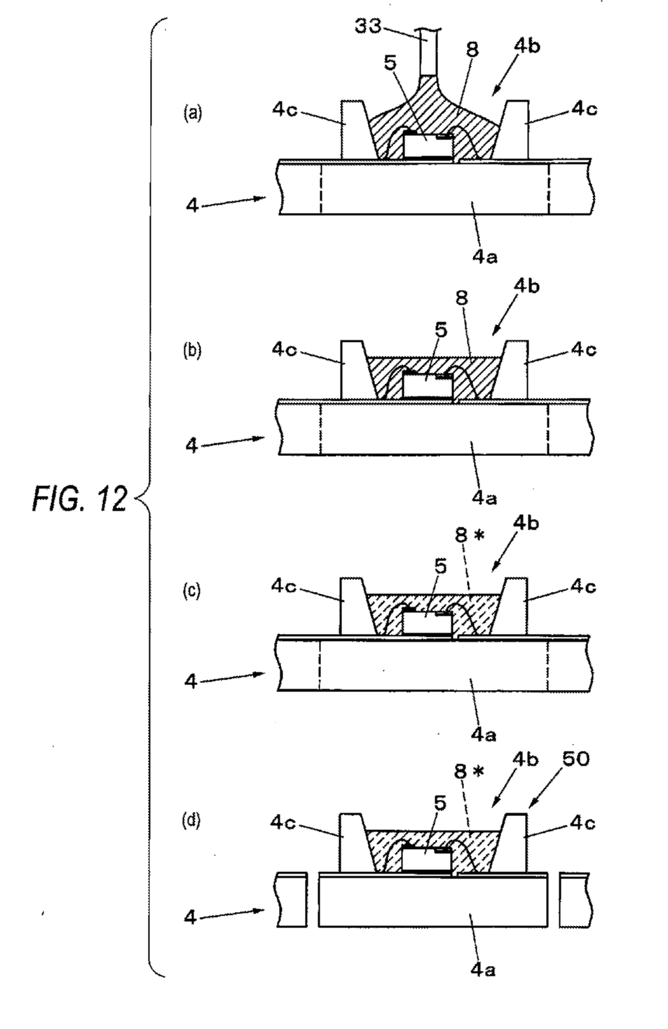

The substrate 4 having undergone wire bonding operation is carried to the resin coating machine M4 (ST6). As shown in FIG. 12(a), in the resin coating machine M4, the resin 8 is discharged from the discharge nozzle 33 into the interior of the LED populating section 4b surrounded by the reflection section 4c. At this time, a specified quantity of resin 8 shown in FIG. 12(b) is applied so as to cover the LED element 5 according to the map data 18 and the resin coating information 14 (ST7). Next, the substrate 4 is sent to the curing machine M5 and heated by the curing machine M5, thereby curing the resin 8 (ST8). As shown in FIG. 12(c), the resin 8 that is applied over and covers the LED element 5 is thermally cured, to thus turn into a resin 8*. Thus, the resin 8 becomes fixed within the LED populating section 4b. The substrate 4 whose resin has become cured is sent to the piece cutting machine M6, where the substrate 4 is cut into the substrate pieces 4a. As shown in FIG. 12(d), the pieces of LED packages 50 are thereby divided (ST9). The LED packages 50 are thereby completed.

The thus-completed LED packages 50 are carried into the emission characteristic inspection machine M7 (ST10), where each of the LED packages 50 undergoes emission characteristic inspection (ST11). Specifically, the emission characteristic inspection machine M7 inspects each of the LED packages 50 in connection with its emission characteristic and detects a deviation between a specified emission characteristic and the thus-detected emission characteristic and feeds back the inspection result to the resin coating machine M4. The resin coating machine M4 received the feedback signal determines whether or not the detected deviation exceeds an acceptable value by the coating information update section 84 (ST12). When the deviation exceeds the acceptable value, the coating information update section 84 updates the resin coating information 14 according to the detected deviation (ST13). Operations, such as the component populating operation and the resin coating operation, are continually carried out by use of the thus-updated resin coating information 14 (ST14). When the deviation is determined not to exceed the acceptable value in (ST12), processing proceeds to a process pertaining to (ST14) while the existing resin coating information 14 is maintained.

As mentioned above, the LED package manufacturing system 1 described in connection with the embodiment adopts a configuration made up of the followings: namely, the component populating machine M1 that populates the plurality of LED elements 5 on the substrate 4; the element characteristic information providing unit that provides, as the element characteristic information 12, information acquired as a result of an emission wavelength of each of the plurality of LED elements 5 having been preliminarily measured; resin information providing unit that provides, as resin coating information 14, information which makes a coating quantity of resin 8 appropriate for producing the LED packages 50 having the specified emission characteristic correlated with the element characteristic information 12; the map data preparation unit for preparing, for each substrate 4, the map data 18 that correlate the populating position information 71a showing a position of the LED element 5 populated on the substrate 4 by the component populating machine M1 with the element characteristic information 12 about the LED element 5; the resin coating machine M4 that applies the coating quantity of resin 8 appropriate for exhibiting a specified emission characteristic to each of the LED elements populated on the substrate 4 according to the map data 18 and the resin coating information 14; the emission characteristic inspection machine M7 that inspects emission characteristics of the LED elements 5 coated with the resin 8, to thus detect deviations from the specified emission characteristics, and that feeds back an inspection result to the resin coating machine M4; and the coating information update unit that performs operation for updating the resin coating information 14 according to the fed-back inspection result when the detected deviation exceeds an acceptable value.

The resin coating machine M4 employed in the LED package manufacturing system 1 having the foregoing configuration includes the resin discharge mechanism 37 that discharges the resin 8 supplied by the resin feed section 38 from the discharge nozzle 33; the nozzle transfer mechanism 35 that relatively transfers the discharge nozzle 33 with respect to the substrate 4; and the coating control section 36 that controls the resin discharge mechanism 37 and the nozzle transfer mechanism 35 according to the transmitted map data 18 and the resin coating information 14, thereby coating each of the LED elements 5 with the quantity of resin 8 appropriate for exhibiting a specified emission characteristic.

This makes it possible to apply the appropriate quantity of resin 8 at all times according to an emission characteristic of the LED element 5 to which the resin 8 is to be applied. Even when variations exist in emission wavelengths of the pieces of LED elements, emission characteristics of the LED packages can be made uniform, thereby enhancing a production yield. The resin coating information 14 can be fixedly applied to an LED package manufacturing system for practical production that is used after having sufficiently performed trial production in preparation for mass production. Therefore, the emission characteristic inspection machine M7 and the coating information update unit in the LED package manufacturing system 1 having the foregoing configuration can be omitted.

The LED package manufacturing system 1 having the foregoing configuration shows a configuration in which the supervisory computer 3 and the respective machines, from the component populating machine M1 to the emission characteristic inspection machine M7, are connected by the LAN system 2. However, the LAN system 2 is not an indispensable configuration requirement. Specifically, the function of the LED package manufacturing system 1 exemplified in connection with the embodiment can be materialized, as long as the following unit are provided; namely, storage unit that stores, for each of the LED packages 50, the element characteristic information 12 and the resin coating information 14 which have been preliminarily prepared and transmitted from the outside; data providing unit capable of providing from the storage unit, as required, the element characteristic information 12 to the component populating machine M1 and the resin coating information 14 and the map data 18 to the resin coating machine M4; and data transmission unit capable of feeding back an inspection result of the emission characteristic inspection machine M7 to the resin coating machine M4.

The present invention is also scheduled to be susceptible to various alterations and applications by skilled artisans without departing the gist and scope of the present invention according to the descriptions of the specification and well-known techniques, and the alterations and applications shall fall within a range where protection of the invention is sought. Moreover, the constituent elements described in connection with the embodiment can also be arbitrarily combined without departing the gist of the present invention.

The present patent application is based on Japanese Patent Application (JP-2010-201653) filed on Sep. 9, 2010, the entire subject matter of which is incorporated herein by reference.

### INDUSTRIAL APPLICABILITY

The LED package manufacturing system of the present invention yields an advantage of the ability to make emission characteristics of LED packages uniform even when variations exist in emission wavelengths of pieces of LED elements, thereby enhancing production yield. The system can be utilized in a field of manufacture of LED packages, each of which is configured by covering an LED element with a phosphor-containing resin.

### DESCRIPTIONS OF THE REFERENCE NUMERALS AND SYMBOLS

1 LED PACKAGE MANUFACTURING SYSTEM
2 LAN SYSTEM
4 SUBSTRATE
4a SUBSTRATE PIECE
4b LED POPULATING SECTION
5 LED ELEMENT
50 LED PACKAGE
8 RESIN
12 ELEMENT CHARACTERISTIC INFORMATION
13A, 13B, 13C LED SHEET
14 RESIN COATING INFORMATION
18 MAP DATA
23 RESIN ADHESIVE INFORMATION
24 ADHESIVE TRANSFER MECHANISM
25 COMPONENT FEED MECHANISM
26 COMPONENT POPULATING MECHANISM
32 RESIN DISCHARGE HEAD
33 DISCHARGE NOZZLE

1. An LED package manufacturing system that manufactures an LED package which is formed by covering an LED element populated on a substrate with a phosphor-containing resin, the system comprising:
a component populating machine that populates the plurality of LED elements on the substrate;
an element characteristic information providing unit that provides, as element characteristic information, information obtained by preliminarily, individually measuring emission characteristics including emission wavelengths of the plurality of LED elements;
a resin information providing unit that provides, as resin coating information, information which makes a coating quantity of resin appropriate for obtaining an LED package having a specified emission characteristic correlated with the element characteristic information;
a map data preparation unit that prepares, for each substrate, map data which correlate populating position information showing positions of then LED elements populated on the substrate by the component populating machine with the element characteristic information about the LED element; and
a resin coating machine that coats, according to the map data and the resin coating information, the respective LED elements populated on the substrate with the coating quantity of resin appropriate for exhibiting the specified emission characteristic.

2. The LED package manufacturing system according to claim 1, wherein both the component populating machine and the resin coating machine are connected to a LAN system; and the element characteristic information providing unit and the resin information providing unit transmit the element characteristic information and the resin coating information read from external storage unit to the component populating machine and the resin coating machine by the LAN system.

3. The LED package manufacturing system according to claim 1, wherein the map data preparation unit is provided in the component populating machine, and the map data are transmitted from the component populating machine to the resin coating machine.
